(19) United States
(12) Patent Application Publication
(10) Pub. No.: US 2012/0085029 A1
(43) Pub. Date: Apr. 12, 2012

(54) VEHICLE OPENING DEVICE

(75) Inventors: Alfons Stockschlager, Viersen (DE); Klaus Hanndorf, Krefeld (DE); Norbert Heller, Viersen (DE)

(73) Assignee: GDX North America Inc., Dover, DE (US)

(21) Appl. No.: 12/279,496

(22) PCT Filed: Feb. 16, 2007
(86) PCT No.: PCT/IB07/00391

§ 371 Date: Oct. 30, 2009

(30) Foreign Application Priority Data
Feb. 17, 2006 (GB) 0603249.4

(51) Int. Cl. B60J 10/02; G01R 27/08; B60J 10/08

(52) U.S. Cl. 49/31; 324/693

(57) ABSTRACT

A sensing assembly for sensing a body part in a window opening or a boot opening is described. The sensing assembly includes first and second electrically conductive members and electrically oscillating means for applying an electrically oscillating signal to the second electrically conductive member. The electric field generated by the applied signal is concentrated in the opening region, and if a body part is within the opening closing movement of the window or hoot is halted.

This invention relates to a sensing assembly for sensing a body part in an opening, such as a vehicle window opening or a vehicle boot opening.

According to the invention there is provided a sensing assembly for sensing a body part in an opening, said assembly comprising:

a flexible seal member adapted to be positioned adjacent to said opening;

a first electrically conductive member within said flexible sealing member;

a second electrically conductive member within said flexible sealing member;

and electrically oscillating means for applying electrically oscillating signals to at least one of said electrically conductive members;

said first and second electrically conductive members being differently shaped such that when said electrically oscillating signal is applied to said at least one electrically conductive member an electric field generated by application of said signal is concentrated in a preferred direction.

According to the invention there is also provided a sensing assembly for sensing a body part in a window opening, wherein said flexible sealing member is adapted to be positioned adjacent to the window opening; a first electrically conductive member within said flexible sealing member; a second electrically conductive member within said flexible sealing member, separated from said first electrically conductive member; electrically oscillating means for applying electrically oscillating signals to at least one of said electrically conductive members; said first electrically conductive member and said second electrically conductive member being differently shaped such that when said electrically oscillating signal is applied to said at least one electrically conductive member an electric field generated by application of said signal is concentrated in the vicinity of the window opening.

In a preferred embodiment of the invention said second electrically conductive member is located in said flexible sealing member such that when a body part positioned between a moving window and a window frame contacts said flexible sealing member, said second electrically conductive member is moved towards but does not contact said first electrically conductive member, and said movement of said second electrically conductive member changes the capacitance between said first and second electrically conductive members and stops movement of said window.

Also in this embodiment of the invention said second electrically conductive member is located in said flexible sealing member, such that when a body part positioned between a moving window and a window frame contacts said flexible sealing member, said second electrically conductive member is moved to physically contact said first electrically conductive member and said physical contact breaks the circuit driving the movement of said window thereby stopping movement of said window.

According to the invention there is also provided a sensing assembly for sensing a body part in a boot opening of an automobile, said assembly comprising: a first flexible sealing member and a second flexible seal member; said first flexible sealing member including first and second electrically conductive members within said flexible sealing member, said second electrically conductive member separate from said first electrically conductive member; said second flexible sealing member including a third electrically conductive member; said first flexible sealing member is located on one of a boot interior or a boot lid and said second flexible sealing member is located on the other of said boot interior or said boot lid; and electrically oscillating means for applying electrically oscillating signals of the same potential to at least one of said first and second electrically conductive members and said third electrically conductive members such that an electric field is radiated from both said flexible seal members; whereby when said boot lid automatically closes movement of the lid will be halted if an electric field radiated from said electrically conductive members in said first flexible sealing member is disturbed due to the presence of a body part in the boot opening.

Embodiments of the invention will now be described, by way of example only, with reference to the accompanying diagrammatic drawings in which:

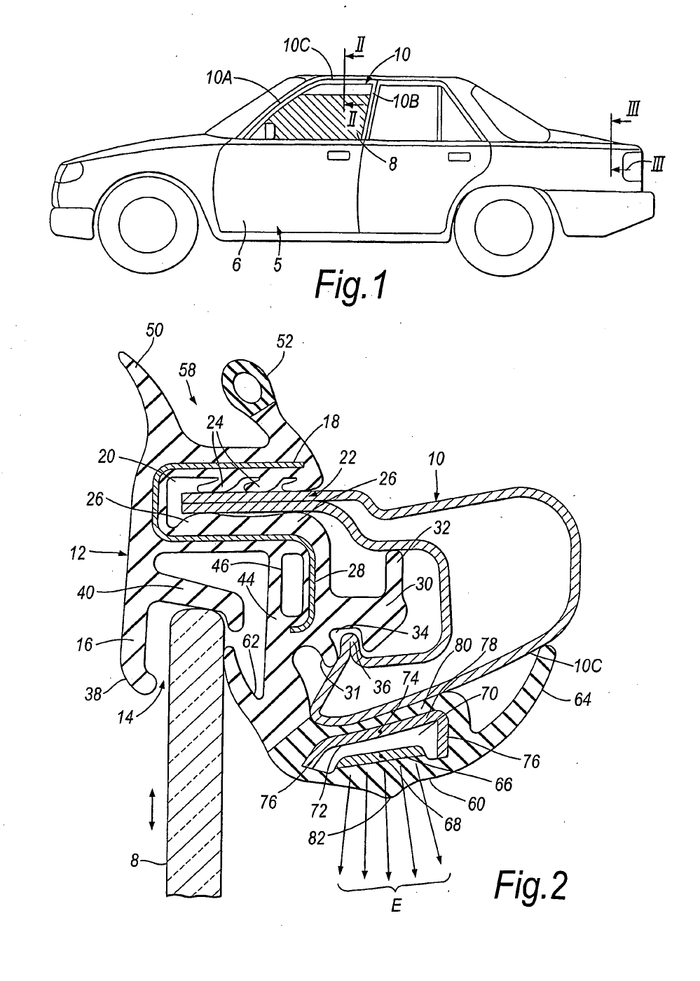

FIG. 1 is a diagrammatic side elevation of a motor vehicle;

FIG. 2 is a cross-sectional view along line II-II of FIG. 1 of the window frame with a sealing and guiding strip showing an arrangement according to a first embodiment of the invention;

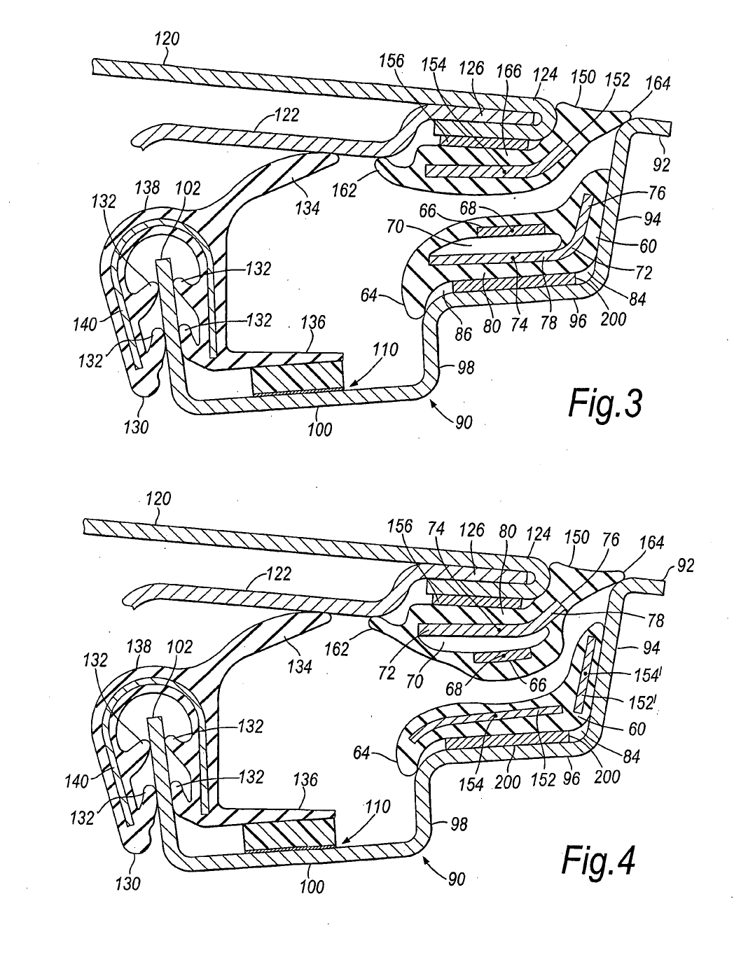

FIG. 3 is a cross-sectional view along line III-III in FIG. 1 through an automobile boot showing an arrangement according to a second embodiment of the invention;

FIG. 4 is a cross-sectional view along line III-III in FIG. 1 through an automobile boot showing an alternative arrangement according to the second embodiment of the invention;

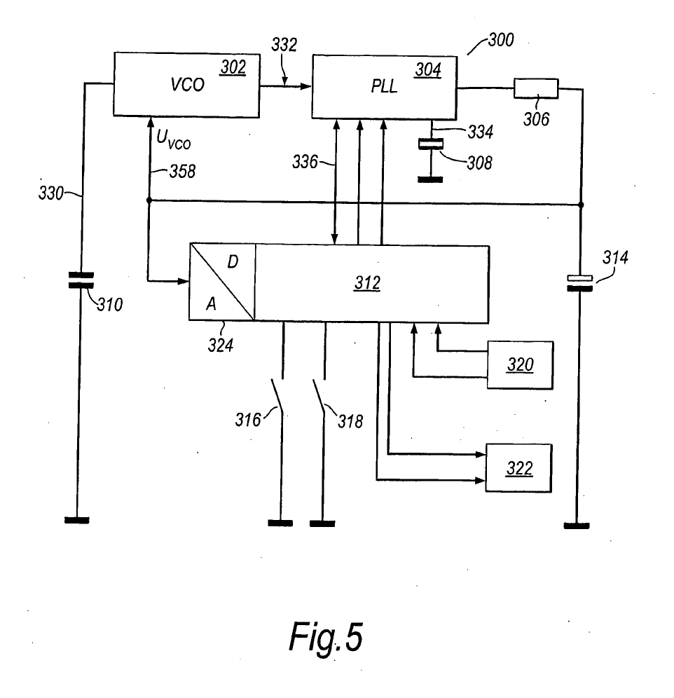

FIG. 5 is a block circuit diagram for the system shown in FIG. 2.

In the drawings, like elements are generally designated with the same reference numeral.

FIG. 1 shows a motor vehicle 5 having a front door 6 with a power-driven window 8 which is shown cross-hatched for clarity. The power-driven window 8 is raised and lowered by means of a suitable motor, normally an electric motor, under the control of switches positioned within the vehicle for use by the driver or passenger. All or some of the other side windows in the vehicle may also be power-driven.

The window frame 10, forming part of the vehicle door, incorporates a window guide channel 12 one form of which is shown in FIG. 2. The window guide channel comprises extruded plastics or rubber material which incorporates an embedded metal core or carrier 18.

The carrier 18 may take any suitable form. For example, it may comprise a simple channel of metal. The channel could additionally be formed with apertures to increase its flexibility. Instead, the carrier could be made from U-shaped metal elements arranged side-by-side to define the channel and either connected together by short flexible interconnecting links or entirely disconnected from each other. The metal could be steel or aluminium, for example.

Instead, the carrier could be made of metal wire looped to and fro to define the channel.

The carrier 18 is advantageously incorporated into the extruded material by a known cross-head extrusion process.

In this embodiment the carrier 18 is C-shaped, with an extension piece 28 extending down from one of the arms of the C-shaped channel. Between extension piece 28 and sidewall 44 is a hollow chamber 46. Advantageously, metal carrier 18 within the window guide channel 12 where it runs along the top part 10C of the window frame (FIG. 1) is separated from the metal carrier 18 in those parts of the window guide channel 12 fitted to parts 10A and 10B of the window frame.

The extruded material defines a lip 40 projecting outwardly from a sidewall of the channel 12, a lip 62 directed inwardly into the channel from sidewall 44 of the channel and a similar lip 38 on the opposite side of the channel but of shorter extent.

The area 14 between window 8 and lip 38 of channel 12 is glass receiving channel 14.

The window frame 10 (FIG. 1) may take the form of a metal channel which is sized to receive the window guide channel 12 as shown in FIG. 2. When the channel 12 is fitted into position within this frame, lips 24 and 26 (FIG. 2) overlap and grip the outsides of the window frame 10, specifically lips 24 contact panel 22 of window frame 10.

The window guide channel 12 extends around the sides and top of the frame 10. Thus, it extends up that part 10A of the frame alongside the “A” pillar of the vehicle, along the top 10C of the frame and down that part 10B of the frame corresponding to the “B” pillar. Where the window glass 8 slides into and out of the lower part 5A of the door 5, a waist-seal (not shown) is provided on each side of the slot.

The surfaces of the window guide channel 12, and of the waist-seal, which contact the sliding glass are advantageously covered in flock or other suitable material to provide a low-friction and substantially weather-proof surface.

The window guide channel 12 also has a portion 30 which is clipped into window frame 10C and also holds the window guide channel in position. Lips 32 and 31 contact parts of window frame 10C to hold window guide channel 12 in position.

As shown in FIG. 2, window guide channel 12 includes sealing member 52 and sealing lip 50 on the outside of the window frame. Sealing member 52 and sealing lip 50 engage the frame of the door opening when the door 5 is closed, to provide a seal around the edge of the door 5.

Window guide channel 12 also includes flexible seal member 60. This may be formed of the same extruded plastic or rubber material as window guide channel 12 or a different material. It may be formed integrally with window guide channel 12, or as a separate element to be joined to window guide channel 12. Seal member 60 may be joined to window guide channel 12 during the moulding operation which forms window guide channel 12 or they may be joined by applying an adhesive.

The connection between window guide channel 12 and seal member 60 is not an essential feature of the invention. Flexible seal member 60 is located on the underside of window frame 10, inside of the car at a distance from window 8.

Embedded in seal member 60 are an outer electrically conductive member 72 and an inner electrically conductive member 66. The inner and outer electrically conductive members are separated by hollow chamber 70. Wire 74 is located within and runs the length of outer electrically conductive member 72, and wire 68 is located within and runs the length of inner electrically conductive member 66. One end of wire 68 is connected to VCO 322 (see FIG. 5) and one end of wire 74 is connected to ground. Of course, these connections could be the other way round. The other end of wires 74 and 68 are connected together by an electrical component, such as a resistor for example.

Preferably, the inner and outer electrically conductive members 72, 66 are made of electrically conductive rubber. The remainder of flexible seal member 60 is preferably made from insulating rubber. Preferably wires 74 and 68 are metal wires.

Outer electrically conductive member 72 has a main body portion 78 and side portions 76 which extend away from main body portion 78 towards the inner electrically conductive member 66. The outer electrically conductive member 72 is thus substantially channel-shaped and the inner electrically conductive member 66 is located on the opposite side of hollow chamber 70 within, and extending lengthwise of, the channel defined by the outer electrically conductive member 72.

It is understood that the extruded plastic or rubber material of flexible seal member 60 electrically insulates the inner and outer electrically conductive members 66 and 72 from the vehicle bodywork.

Flexible seal member 60 also has seal region 80 located between the main body portion 78 and window frame 10C. Seal region 80 contacts window frame 10C. Extending away from seal member 60, on the opposite side of the seal member 60 to window 8 is lip seal 64 which engages with window frame 10C.

Seal member 60 also includes protrusion 82, located on the underside of flexible seal member 60 below inner electrically conductive member 66. The protrusion 82 is separated from inner electrically conductive member 66 by a part of the body of flexible seal member 60.

In the usual way, when a driver or passenger of the vehicle wishes to raise or lower a window they operate an appropriate switch to energise the motor, and the window glass moves either up or down (as desired) within the guide channel 12.

The system now to be described is for detecting a body part (e.g. a hand) which may have been placed within a gap between the window glass 8 and the window frame 10. The system will detect such an obstruction when it comes within a predetermined distance of flexible seal member 60. In a preferred embodiment the motor driving the window glass will stop and/or reverse the window movement to prevent the body part from becoming trapped (and possible injured) in the region between the top of the window glass 8 and the window frame 10C.

FIG. 5 shows a circuit 300 for energising motor 322 for raising and lowering the window glass 8.

The circuit of FIG. 5 has a first oscillator 308, which is quartz-stabilised and has an output frequency (in this example) of 4 MHz. The output of oscillator 308 passes on line 334 to phase detector 304. Typically, the quartz oscillator and the phase detector 304 are integral components of an electronic component, such as a Motorola MC145155-2 chip (Motorola CMOS application specific digital analogue integrated circuits 5-53, MC145151-2 Series page 9).

Hall detectors 320 are connected to a micro-controller 312 and are used for detecting the position of the window 8. Motor 322 for driving the window up and down is connected to the micro-controller 312 and switches 316 and 318 for moving the window up and down respectively are also connected to micro-controller 312.

The circuit 300 also includes a second oscillator 302, which is a Voltage Controller Oscillator (VCO) and is supplied on line 358 with a control voltage Uvco. This oscillator 302 is nominally at 1.85 MHz.

The RF output of voltage controlled oscillator 302 is fed along line 332 to phase detector 304 where it is compared with the frequency of the quartz-stabilized oscillator 308. As a result of the comparison the phase detector 304 produces an output of control voltage Uvco.

The VCO 302 and the phase detector 304 form a phase locked loop. The control voltage Uvco is supplied to the VCO 302 by the phase detector 304 via a loop filter formed by a capacitor 314 and resistor 306.

The phase detector 304 includes a divider (not shown) which is set by the micro-controller 312, so that the initial control voltage Uvco supplied to VCO 302 over line 358 is 1 volt, this initial value is also supplied to the micro-controller 312 over line 336 where it is stored as a reference value.

The micro-controller 312 also includes A/D converter 324 which also receives the instantaneous control voltage Uvco when the window glass starts to rise.

Line 330 connects the VCO 302 to one side of capacitor 310, formed by outer electrically conductive member 72 and inner electrically conductive member 66. The other side of capacitor 310 is connected to ground. Preferably VCO 302 is connected to inner electrically conductive member 66 and outer electrically conductive member 72 is connected to ground.

When the wire 68 in inner electrically conductive member 66 is energised by oscillator 302 an electric field is radiated and is present within the area of the window frame 10. The relationship between the arrangement of the two electrically conductive members 66, 72 is such that electric field lines are concentrated in the vicinity of the window opening. This is because the inner and outer electrically conductive members 66, 72 are significantly differently shaped. More specifically, in this embodiment, side portions 76 of the outer electrically conductive member 72 are directed towards the inner electrically conductive member 66 to define a channel, and the inner electrically conductive member 66, which is relatively flat, extends lengthwise of the channel, in this example wholly within the channel.

Electric field lines generated by this arrangement are represented by arrows E in FIG. 2. As depicted in that Figure, the field lines are concentrated in the vicinity of the window opening; elsewhere, for example outside the window opening or within the interior of the vehicle, the field lines are much less dense.

The concentration of field lines in the vicinity of the window opening gives the sensing assembly greater sensitivity to the presence of a body part such as a hand within the opening.

When the window is open, closing switch 316 will cause the window to be raised automatically by motor 322. During the movement of the window upwards, the instantaneous frequency of VCO 302 is continually detected at phase detector 304 and compared with reference output from quartz stabilised oscillator 308. The control voltage Uvco resulting from the comparison is output to micro-controller 312 along line 336 to be compared with the stored reference value of the control voltage.

If the difference between the instantaneous voltage Uvco and the stored reference value is below a certain preset threshold then the window will continue to move upwardly. The threshold is set to be dependent on the position of the window in the window opening and is such that the window will close, even if the window is wet, when there are no obstacles with high dielectric constant within the vicinity of the electric field in the opening.

If an obstacle with a relatively high dielectric constant e.g. a human hand or body part is within the vicinity of the radiated electric field this will cause a change in the capacitance of capacitor 310. This change in capacitance will lead to a change in the frequency of VCO 302. The altered frequency is received along line 332 at phase detector 304 where it is compared with the reference frequency of quartz oscillator 308. The control voltage Uvco resulting from the comparison is output to micro-controller 312 and the value of control voltage Uvco is compared with the stored reference value. If the difference between the two voltage values exceeds the same preset threshold, this indicates that the output frequency of VCO 302 has charged sufficiently to indicate the presence of a body part in the vicinity of the electric field in the window opening.

In this case the micro-controller 312 will stop and preferably reverse the window, thus preventing damage to the body part in the window opening.

The system can also be set so that the rising window is stopped before, the hand or other body part actually makes contact with the top 10C of the window frame. Instead, it can be set so that the window stops when the hand or other body part is in actual contact with the top 10C but before the rising window applies more than a predetermined and non-injurious force to the hand or other body part (e.g. 100 N).

Environmental changes, e.g. rainfall may also cause a small change in the capacitance of the capacitor 310. In this case, the small change in capacitance will cause a change in frequency of VCO 302, which is detected by phase detector 304. Phase detector 304 performs the above described comparison and outputs an instantaneous control voltage Uvco. As described above a comparison of the value of the instantaneous control voltage and the stored reference value is performed in micro-controller 312. This result of the comparison will be below the threshold and movement of the window will not be stopped or disabled as a result of the environmental conditions. The instantaneous control voltage Uvco will also be provided to VCO 302 along line 358 and will tend to compensate the change in capacitance by appropriately adjusting the frequency of oscillator 302.

Of course, other types of control circuit may be used to produce the required electric field. The rising window glass on its own (that is, when no human hand or other body part is present in the gap between the glass and the top 10C of the window frame) does not of itself significantly affect the output of the VCO 302. This is because the dielectric constant of the window glass is many times less than that of a human hand or other body part.

The system can also be adapted for frameless windows. In this case, there is no separate window frame. The rising and lowering window glass slides with respect to a seal or channel carried by the frame on the vehicle body within which the door is located. This channel or seal (such as a door seal) will normally also incorporate inner and outer electrically conductive members 66, 72 which can thug be connected to receive the output of the VCO 302 in the manner already explained.

In the system of FIG. 2, protrusion 82 is located on the underside of flexible seal member 60 such that any body part on the rising edge of window glass 8 will eventually contact protrusion 82 as the window glass rises to its closed position. Contact between a body part and protrusion 82 will cause deformation of flexible seal member 60 and inner electrically conductive portion 66 will be moved towards the outer electrically conductive portion 72. This movement of inner conductive member 66 will cause a change in capacitance of capacitor 310 defined by the two electrically conductive members 66 and 72 when they are energised by VCO 302. Like the non-contact detection mode previously described, this change in capacitance will cause a change in the frequency of VCO 302. Again, this change in frequency will be detected by the phase detector 304 and will cause the motor 322 to be de-energised as described above, thereby immediately stopping the rising window glass.

Also, it is possible that movement of inner electrically conductive member 66 may be so great, that it moves through the hollow chamber 70 and physically contacts outer electrically conductive member 72. In this case, there will be electrical contact between the two electrically conductive members 66 and 72, and when they are energised this will cause a short circuit. Once again, this interruption of the control circuitry will cause motor 322 to be de-energised as described above, thereby immediately stopping the rising glass, if for some reason it has not been stopped already.

As described above, the sensing assembly can detect the presence of body parts in a window opening in three different ways. Firstly, non-contact detection where the body part in the window opening changes the capacitance of capacitor 310 due to a change of dielectric constant; secondly, contact between a body part and protrusion 82, causing movement of inner electrically conductive member 66 towards outer electrically conductive member 72, again, changing the capacitance of capacitor 310 and finally, contact between a body part and protrusion 82, causing physical contact (and resulting short circuit) between inner and outer electrically conductive members 66 and 72.

FIG. 3 shows a cross-section along lines III-III of FIG. 1 illustrating an alternative embodiment of the invention. One side of boot lid 120 is shown. The lid 120 incorporates a stiffening plate 122 in the form of a sheet metal plate which is welded or otherwise secured to the lid 120. Edge 126 of plate 122 is directed towards edge 124 of lid 120 and is held in flanged engagement with lid 120. Vehicle body panel 90 is composed of panel 92, panel 94 approximately at right angels to panel 92, then panel 96 at the edge of the boot opening, panel 98 approximately at right angles to panel 96, panel 100 providing a drainage groove, and at approximately right angles to panel 98 and finally mounting flange 102, substantially parallel to body panel 98. The boot seal 130 includes a U-shaped strip 138 of extruded plastic or rubber material. Metal strip 140 is embedded in U-shaped strip 138 and also has a U-shaped cross-section. Like carrier 18 in the window channel 12, carrier 140 may take any suitable form.

For example, it may comprise a simple channel of metal. The channel could additionally be formed with apertures to increase its flexibility. Instead, the carrier could be made from U-shaped metal elements arranged side-by-side to define the channel and either connected together by short flexible interconnecting links or entirely disconnected from each other. The metal could be steel or aluminium, for example.

Instead, the carrier could be made of metal wire looped to and fro to define the channel.

The carrier is advantageously incorporated into the extruded material 130 by a known cross-head extrusion process.

Sealing lips 132 are located on the inner surface of U-shaped strip 138 and incline upwardly and inwardly to abut mounting flange 102. These lips 132 hold sealing strip 138 firmly in place on mounting flange 102. Sealing lip 134 extends from the section of the sealing strip 138 joining the arms of the U-shaped strip. Lip 134 sealingly abuts stiffening plate 122 when the boot lid 120 is closed. At the other end of sealing strip 138 extending from one of the arms of U-shaped strip is sealing arm 136. This arm contacts block 110 which is located on the inside of panel 100 of body panel 90.

Flexible seal member 60 is located inside the boot, and seal region 80 of seal member 60 is affixed to body panel 96 with adhesive tape 200. Gap regions 84 and 86 are found at either end of adhesive tape 200. Of course, other methods of fixing the seal member 60 to the body panel 90 may be used. In this embodiment of the invention outer electrically conductive member 72 has a main body portion 78 and a side portion 76 extending away from main body portion 78 towards inner electrically conductive member 66 in a direction approximately parallel to body panel 94. The outer electrically conductive member 72 is thus substantially L-shaped. The inner electrically conductive member 66 is approximately parallel to main body portion 78 of outer electrically member 72. Like the embodiment shown in FIG. 2, seal member 60 is also provided with hollow chamber 70, and electrically conductive members 72 and 66 have wires 74 and 68 respectively located within their main body portions. Like the first embodiment of the invention wires 74 and 68 run along the entire length of the electrically conductive portions 72 and 66. The electrical connection at the ends of the wires are the same as described for the embodiment shown in FIG. 2.

In this embodiment of the invention lip seal 63 extends away from main body 80 of seal member 60 to abut the body panel 90 at the region where panel 96 meets panel 98.

A second flexible seal member 150 is also shown in FIG. 3. This seal member 150 is affixed to the boot lid 120 by means of adhesive tape 156. Of course, alternative methods of fixing seal member 150 to boot lid 120 may be envisaged. Seal member 150 is provided with a main body portion 166 and sealing lips 162 and 164 extending from either end of main body portion 166. Sealing lip 162 abuts stiffening plate 122 of boot lid 120, and sealing lip 164 abuts vehicle body panel 90 at the junction of panels 92 and 94 when the boot lid is closed. Inside main body portion 166 of flexible seal member 150 is an electrically conductive member 152, and wire 154 is located inside member 152. Like the wires 74 and 68 in electrically conductive members 72 and 66 of flexible seal member 60, wire 154 runs along the length of electrically conductive member 152.

There is no physical contact between the flexible seal members 150 and 60 when the boot lid is closed. Flexible seal members 60 and 150 are preferably made from insulating rubber and electrically conductive members 72, 66 and 152 are preferably made of electrically conductive rubber. Wires 74, 68 and 154 are preferably metal wires.

In operation, an electrical oscillator (not shown but similar to voltage controller oscillator 302 in FIG. 5) is connected to one end of wire 68 in the inner electrically conductive member of flexible seal member 60 and one end of wire 154 in electrically conductive member 152 of flexible seal member 150. One end of wire 74 in outer electrically conductive member 72 of flexible seal member 60 is connected to ground. The other ends of wires 68 and 74 are connected together by an electrical component, which is used to ensure continuity in the circuit. The potential of the electrically oscillating signal applied to both wires 68 and 154 is the same. When the electrical oscillator applies an electrically oscillating signal to wires 68 and 154, an electric field will be radiated from both flexible seal members 60 and 150 into the boot opening. Like the embodiment of FIG. 2 the relationship between the arrangement of the two electrically conductive portions is such that the generated electric field is concentrated into the region of the boot opening. The outer electrically conductive member has main body portion 78 and side portion 76 extending away from said main body portion 78 such that the outer electrically conductive portion is substantially L-shaped. The side portion 76 extends past inner electrically conductive portion 66. This arrangement of portion 76 and inner electrically conductive member 66 ensures that the field radiated from flexible seal member 60 is concentrated into the boot opening near the edge of the boot, and not deep inside the boot where obstructions are less likely to be located.

In a motorised boot (control mechanism not shown, but these are generally known in the art) when it is desired to close the boot, a power driven motor will move the boot lid 120 towards the boot interior.

If an obstacle, such as a human body part is within the boot opening whilst the lid is closing, and also within the region of the electric field radiated from the flexible seal member 60, the body part will cause a change in capacitance due to the change in dielectric constant and this will be detected by control circuitry driving the boot and movement of the boot lid will be halted. The control circuitry will be similar to that described with reference to FIG. 5.

If the electrically conductive member 152 in flexible seal member 150 was not at the same electrical potential as inner electrically conductive member 66 in flexible seal member 60, then as the boot lid 120 approached the boot interior to close the boot, the boot lid would cause a change in the electric field radiated from flexible seal member 60, in the same way as the change caused by a sensed body part as described above. This would lead to the movement of the boot being unnecessarily halted.

The application of the same oscillating electric potential to the electrically conductive member 152 of flexible seal member 150 screens the electric field radiated from flexible seal member 60 from the effect of the approaching boot lid 120. The boot lid will not be detected as an obstruction as it closes.

FIG. 4 shows an alternative arrangement for the embodiment shown in FIG. 3. In this embodiment, outer electrically conductive member 72 and inner electrically conductive member 66 (separated by hollow chamber 70) are located within flexible seal member 150, again affixed to boot lid 120 with adhesive tape 156.

Outer electrically conductive member 72 again has main body portion 78 and side portion 76. However, in this embodiment side portion 76 extends away from main body portion 78 in a direction away from inner electrically conductive member 66. The inner and outer electrically conductive members 72 and 66 are again separated by a hollow chamber 70. Like the embodiment of FIG. 3, wires 74 and 68 run along the length of electrically conductive members 72 and 66 of flexible seal member 150. The electrical connections of these wires are as described previously.

Flexible seal member 60 affixed to body panel 96 with adhesive tape 200 has an embedded electrically conductive member 152 with wire 154 embedded along the length of the electrically conductive member 152. Flexible seal member 60 also includes a second electrically conductive member 152′ which includes wire 154′ embedded along its length. The two electrically conductive members 152, 152′ are spaced apart from each other and are separated by part of flexible seal member 60. The second electrically conductive member 152′ is not essential to the invention, and the device would still work if it was not present.

Like the embodiment in FIG. 3, in operation an electrical oscillator is connected to one end of wire 68 in inner electrically conductive member 66 of flexible seal member 150. One end of wire 154 in flexible seal member 60 is also connected to the electrical oscillator. One end of wire 74 in outer electrically conductive member 72 in flexible seal member 150 is connected to ground. The other ends of wires 74 and 68 are connected together by an electrical component to ensure electrical continuity. The electrical oscillator will apply a signal to the wires in the same way as described for FIG. 3. The generation of electric fields and subsequent detection of obstacles such as human body parts is the same as described above for FIG. 3. In this embodiment of the invention, the arrangement of inner and outer electrically conductive members 66 and 72 ensures that the radiated electric field is directed into the vicinity of the boot opening, and not directed to regions where obstacles are unlikely to be detected.

In essence, the devices in FIGS. 3 and 4 operate in the same way, it is merely the arrangement of the internal electrically conductive members in their respective flexible seal members which are interchanged.

Finally, the two boot embodiments of the invention also operate in the two contact modes previously described with regard to FIG. 2.

In FIG. 3, contact between a body part and the exposed part of flexible seal member 60 will cause deformation of flexible seal member 60 and inner electrically conductive member 66 will be moved towards outer electrically conductive member 72. This will cause a change in capacitance of the capacitor formed by the two electrically conductive members 66 and 72 and the subsequent halting of the motor driving the boot lid 120.

Also, if the movement of the flexible seal member 60 is so great that inner electrically conductive member 66 contacts outer electrically conductive member 72, the circuit will be shorted out and the motor driving the boot will be halted.

Flexible seal member 150 in FIG. 4 can also detect body parts through the two contact modes described above.

1. A sensing assembly for sensing a body part in an opening, the sensor assembly comprising:
(a) a flexible seal member adapted to be positioned adjacent to the opening;
(b) a first electrically conductive member within the flexible sealing member;
(c) a second electrically conductive member within the flexible sealing member; and
(d) electrically oscillating means for applying electrically oscillating signals to at least one of the electrically conductive members;
the first and second electrically conductive members being differently shaped such that when the electrically oscillating signal is applied to the at least one electrically conductive member an electric field generated by application of the signal is concentrated in a preferred direction.

2. The sensing assembly according to claim 1, wherein
the flexible sealing member is adapted to be positioned adjacent to the window opening;
the first electrically conductive member and the second electrically conductive member being differently shaped such that when the electrically oscillating signal is applied to the at least one electrically conductive member an electric field generated by application of the signal is concentrated in the vicinity of the window opening.

3. The sensing assembly according to claim 2 wherein the first electrically conductive member is substantially channel shaped and the second electrically conductive member is substantially flat and runs length wise of the channel.

4. The sensing assembly according to claim 3 wherein the first electrically conductive member has a main portion and two side portions extending away from the main portion to define the channel.

5. The sensing assembly according to claim 4 wherein the second electrically conductive member is within the channel defined by the first electrically conductive member.

6. The sensing assembly according to claim 4 wherein the first side portion extends away from the main portion of the first electrically conductive member in a first direction and the second side portion extends away from the main portion in a second direction non-parallel to the first direction.

7. The sensing assembly according to claim 4 wherein the first side portion extends away from the main portion of the first electrically conductive member in a first direction and the second side portion extends away from the main portion in a second direction parallel to said first direction.

8.-17. (canceled)

18. The sensing assembly according to claim 1 wherein the second electrically conductive member is located in the flexible sealing member such that when a body part positioned between a moving window and a window frame contacts the flexible sealing member, the second electrically conductive member is moved towards but does not contact the first electrically conductive member, and the movement of the second electrically conductive member changes the capacitance between the first and second electrically conductive members and stops movement of the window.

19. The sensing assembly according to claim 1 wherein the second electrically conductive member is located in the flexible sealing member, such that when a body part positioned between a moving window and a window frame contacts the flexible sealing member, the second electrically conductive member is moved to physically contact the first electrically conductive member and the physical contact breaks a circuit driving the movement of the window thereby stopping movement of the window.

20. The sensing assembly according to claim 1 wherein the flexible sealing member includes a protrusion located on the underside of the flexible sealing member in the window opening, for contacting a body part in the opening.

21. A sensing assembly for sensing a body part in a boot opening of an automobile, the assembly comprising:
(a) a first flexible sealing member;
(b) a second flexible sealing member;
the first flexible sealing member including first and second electrically conductive members within the flexible sealing member, the second electrically conductive member separate for the first electrically conductive member;
the second flexible sealing member including a third electrically conductive member;
the first flexible sealing member is located on one of a boot interior and a boot lid and the second flexible sealing member is located on the other of the boot interior and the boot lid; and
(c) electrically oscillating means for applying electrically oscillating signals of the same potential to at least one of the first and second electrically conductive members and the third electrically conductive member such that an electric field is radiated from both the flexible seal members, whereby when the boot lid automatically closes movement of the boot lid will be halted if the electric field radiated from the electrically conductive members in the first flexible sealing member is disturbed due to the presence of a body part in the boot opening.

22. The sensing assembly according to claim 21 wherein the first and second electrically conductive members in the first flexible seal member are differently shaped such that when the electrically oscillating signal is applied to at least one of the first and second electrically conductive members the electric field generated by application of the signal is concentrated in the vicinity of the boot opening.

23. The sensing assembly according to claim 21 wherein the first electrically conductive member has a main portion and a side portion extending away from the main portion and the second electrically conductive member is substantially parallel to the main portion of the first electrically conductive member.

24.-26. (canceled)

27. The sensing assembly according to claim 23 wherein the side portion of the first electrically conductive member extends away from the main portion of the first electrically conductive member in a direction towards the second electrically conductive member and the boot opening.

28. The sensing assembly according to claim 23 wherein the side portion of the first electrically conductive member extends away from the main portion of the first electrically conductive member in a direction away from the second electrically conductive member.

29.-38. (canceled)

39. The sensing assembly according to claim 21 wherein the second electrically conductive member is located in the first flexible seal member such that when a body part in the boot opening contacts the first flexible seal member, the second electrically conductive member is moved towards but does not contact the first electrically conductive member, and the movement of the second electrically conductive member changes the capacitance between the first and second electrically conductive members and stops movement of the boot lid.

40. The sensing assembly according to claim 21 wherein the second electrically conductive member is located in the first flexible seal member such that when a body part in the boot opening contacts the first flexible seal member, the second electrically conductive member is moved to physically contact the first electrically conductive member, the physical contact breaks the circuit driving movement of the boot lid, thereby stopping movement of the lid.

41. The sensing assembly according to claim 21 wherein the first flexible seal member includes a protrusion protruding from the seal into the boot opening for contacting a body part in the boot opening.

42.-43. (canceled)
